(19) United States
(12) Patent Application Publication
(10) Pub. No.: US 2021/0112673 A1
(43) Pub. Date: Apr. 15, 2021

(54) Concept for a Kickstand of a Computing Device

(71) Applicants: Justin HUTTULA, Portland, OR (US); Aleksander MAGI, Portland, OR (US); Juha PAAVOLA, Hillsboro, OR (US); Karl HAMBERGER, Santa Clara, CA (US); James RAUPP, Hillsboro, OR (US)

(72) Inventors: Justin HUTTULA, Portland, OR (US); Aleksander MAGI, Portland, OR (US); Juha PAAVOLA, Hillsboro, OR (US); Karl HAMBERGER, Santa Clara, CA (US); James RAUPP, Hillsboro, OR (US)

(21) Appl. No.: 17/129,970

(22) Filed: Dec. 22, 2020

Related U.S. Application Data
(60) Provisional application No. 63/007,378, filed on Apr. 9, 2020.

(51) Int. Cl. H05K 5/02; G06F 1/16

(52) U.S. Cl. CPC H05K 5/0234; G06F 1/1607; G06F 1/1654

(57) ABSTRACT

Examples relate to computing devices or apparatuses and to corresponding methods for a computing device. A computing device comprises a display unit comprising a display of the computing device. The computing device further comprises a kickstand. The kickstand is mechanically coupled to the display unit via a sliding mechanism, such that the display unit is adjustable relative to the kickstand along the sliding mechanism.

### FIELD

Examples relate to computing devices or apparatuses and to corresponding methods for a computing device.

### BACKGROUND

A major consideration in the design of workspaces is the ergonomics of the workspace, in particular for office work. In computer-based workspaces, recommendations exist for the placement of the display of the computer relative to the user. In many recommendations, the top of the monitor/display is at eye-level and slightly tilted. Such recommendations often assume the perusal of a separate monitor, which is easy to adjust, since many monitor have adjustable stands. However, laptop computer positioning often does not follow the recommendations, since the laptop is often placed on the desk, making the user look downwards to see the top of the monitor, which may be against the health recommendations. In other words in these cases, the display may be kept on table level. To follow the recommendations, separate stands for laptops can be used that prop up the laptop computer so the top of the monitor is at eye-level. However, such stands may be difficult to carry with a personal computer (PC).

In general, a typical laptop stand is quite heavy, difficult to transfer daily and placed at a user's desk. In many offices, however, there are no more cubicles that are reserved for employees, but unassigned seating at the workplace, which is called hoteling or hot desking. Additionally, personal computers may evolve past the “clamshell” form factor. Foldable, dual displays and mono-block (large tablet) PCs gain increasing market share. Those devices may be difficult to place ergonomically, in particular at unassigned tables without any special stand.

### BRIEF DESCRIPTION OF THE FIGURES

Some examples of apparatuses and/or methods will be described in the following by way of example only, and with reference to the accompanying figures, in which

FIG. 1 shows a schematic diagram of different applications being used on a detachable computing device;

FIGS. 2a and 2b show a front view and a back view of an example of a computing device;

FIG. 2c shows a flow chart of an example of a method for a computation device;

FIGS. 3a to 3i show an example of a computing device from different angles and in different configurations;

FIG. 3j shows another example of a computing device in different configurations;

FIGS. 4a and 4b show schematic diagrams of different positions of a display unit of a computing device relative to a kickstand of the computing device;

FIGS. 5a to 5d show different modes of an example of a computing device;

FIG. 6 shows another example of a computing device in different configurations;

FIG. 7 shows an example of a computing device, in which a display unit of the computing device is tilted around a kickstand of the computing device; and

FIG. 8 shows an example of a computing device with a rotation mechanism in different configurations.

### DETAILED DESCRIPTION

Various examples will now be described more fully with reference to the accompanying drawings in which some examples are illustrated. In the figures, the thicknesses of lines, layers and/or regions may be exaggerated for clarity.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Same or like numbers refer to like or similar elements throughout the description of the figures, which may be implemented identically or in modified form when compared to one another while providing for the same or a similar functionality.

It will be understood that when an element is referred to as being “connected” or “coupled” to another element, the elements may be directly connected or coupled via one or more intervening elements. If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two Elements.

The terminology used herein for the purpose of describing particular examples is not intended to be limiting for further examples. Whenever a singular form such as “a,” “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises,” “comprising,” “includes” and/or “including,” when used, specify the presence of the stated features, integers, steps, operations, processes, acts, elements and/or components, but do not preclude the presence or addition of one or more other features, integers, steps, operations, processes, acts, elements, components and/or any group thereof.

Unless otherwise defined, all terms (including technical and scientific terms) are used herein in their ordinary meaning of the art to which the examples belong.

Examples of the present disclosure provide an integrated variable height and -angle kickstand for display-only personal computers (i.e. computing devices), which may allow for an adjustable height angle and weight distribution for an improved user experience. Examples may provide a convertible kickstand, which is always carried with the device. The following figures present details of this concept and potential user modes.

In general, the concept may be used in a variety of form factors. One form factor the concept is applicable to is a computing platform with a detachable wire-free dual screen with integrated kickstand and keyboard.

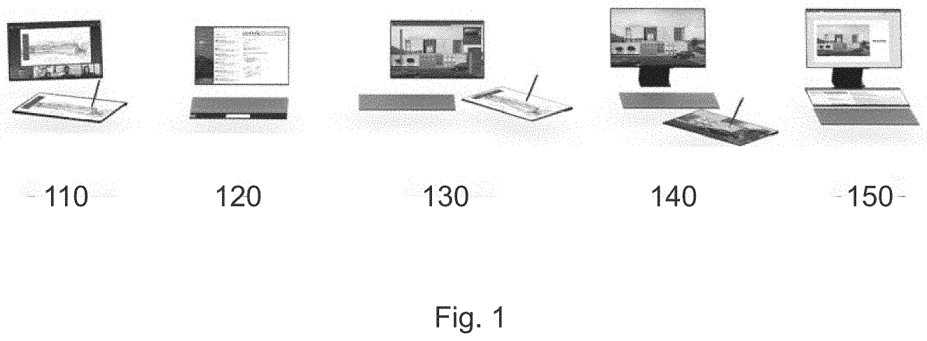

FIG. 1 shows a schematic diagram of different applications being used on such a detachable, integrated computing device. Such an integrated device may provide display space, orientation and ergonomic affordances. For example, video call (using a video-call application) and sketching applications (using a graphics editing application) may be used 110 at the same time with such a device. In some examples, an email application may be used 120, with the second display placed under the keyboard. In some applications, a graphics suite (e.g. a vector graphics application and a graphics editing application) may be used 130, with the second screen being used for sketching and a keyboard being used for inputting text or modifier keys. In some examples, a mobile stand may be used 140 for height, and the second screen may be used for sketching (in a graphics editing application). In some examples, a mobile stand may be used 150 for dual screen usage, e.g. to work in a presentation application and a mail application at the same time. The concept may be display-size agnostic, e.g. applicable to 13″, 15″ or 17″ devices.

One of the displays of such a detachable-wirefree dual screen device may be seen as a mono-block device, such as a Microsoft Surface tablet, and not a laptop with an attached keyboard or base and not an accessory attachment. It may be equipped with an integrated mechanism that allows tablet designs, like a Microsoft Surface, to have a raising and lowering screen, with angular adjustment, and, without a separate stand. This may provide improved ergonomics, usability and mobility. Examples may provide a liftable and adjustable kickstand, so that a mono-block (large tablet type PC), detachable dual display or foldable PC that can be lifted and adjusted in an ergonomic position on the table. Form factors that benefit from elevated display include, but are not limited to: tablet, laptop, pAIO (portable All in One), AIO (All in One), detachable, convertible. Example may provide a slidable kickstand in a mono-block or dual display PC. Thus the display can be lifted easily on the ergonomic level, adjusted in comfortable position, or turned around to show a presentation in a meeting room. Such a concept may address the ergonomic recommendations outlined above. Examples may further address cooling challenges, since the device is not placed on the top of separate stand. Example may provide an improved user experience (UX) of raising the screen (i.e. display) up and down, and, rotating the screen to flat and completely around to share with users on the other side. The battery, which adds weight to the concept, may be placed on the bottom, e.g. so the center of gravity is less than half of total height, allowing for solid foundation and balance. In various examples, battery and cables may be navigated through the hinges. Examples may provide a rotatable, raiseable and sharable form factor in Co-Working spaces. For example, cable management may be provided at the left (or right) side bottom of the base, keeping cables away from eye level and pain points. In contrast to examples, laptops might not allow for small space usage. The mono-block concept may allow for smaller space usage (airplane, train) due to smaller footprint and improved ergonomics. In the following, a proof of concept of the mechanism, usability and use modes is shown.

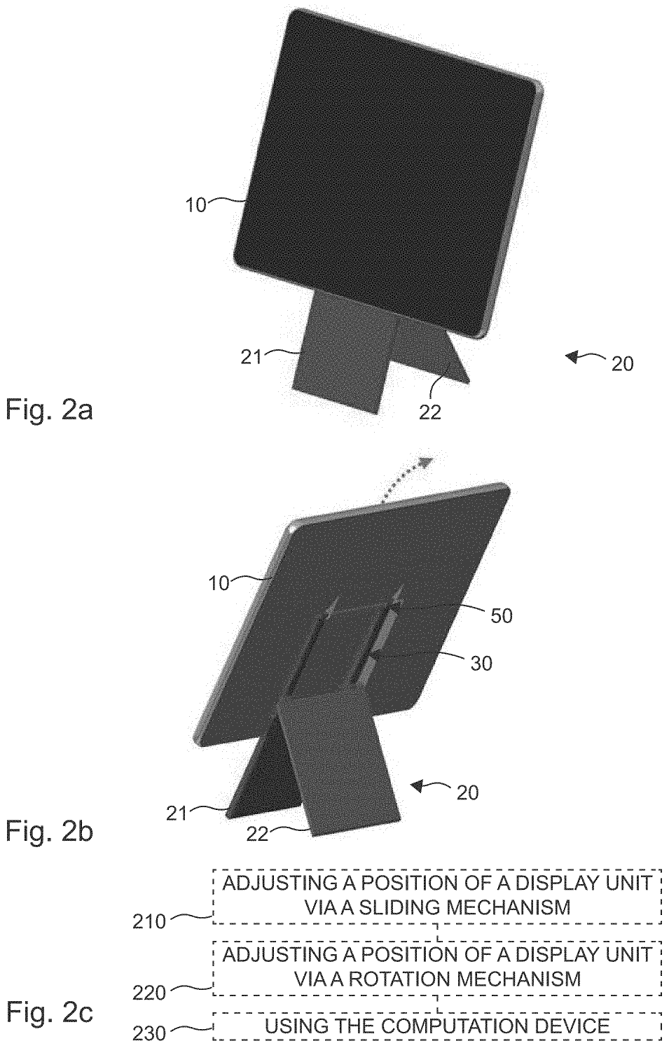

FIGS. 2a and 2b show a front view and a back view of an example of a computing device. The computing device comprises a display unit 10 comprising a display (or display means) of the computing device. The computing device comprises a kickstand 20. The kickstand is mechanically coupled to the display unit via a sliding mechanism (or sliding means) 30, such that the display unit is adjustable relative to the kickstand along the sliding mechanism (or sliding means). Examples further provide a corresponding computing apparatus with a display unit, a kickstand and sliding means, with the display unit comprising display means. The components of the computing apparatus are introduced as component means, which may be implemented by the respective components of the computing device. Examples of the present disclosure further provide a method for adjusting such a computing device (shown in FIG. 2c), with the method comprising adjusting the display unit relative to the kickstand via the sliding mechanism 30 of the computing device.

Various examples of the present disclosure relate to a computing device, such as the computing device shown in connection with FIGS. 2a to 8. In general, a computing device may be a device that comprises a processor configured to perform computations. For example, the computing device may comprise one or more processors (for performing computations), one or more interfaces (for exchanging data) and one or more storage devices (for storing data). In various examples, the computation device may be a portable computation device, i.e., a computation device that can be carried around and operated without relying on a wireline connection to a power outlet. For example, the computation device may comprise a re-chargeable battery.

There are various examples of portable computation devices. For example, laptop computers are portable computation devices, as are tablet computers. Laptop computers may essentially comprise two sections—a first section comprising the main circuitry of the laptop computer, and a second section comprising a display of the laptop computer. In laptop computers, these two sections may be permanently connected via a (non-removable) hinge. Various examples of the present disclosure, however, relate to a mono-block computing device. In other words, the computing device may be a mono-block computing device. A mono-block computing device may be a computing device that comprises a single section, i.e. all of the components of the computing device may be stored within recesses of a single block of the computing device, in contrast to laptop computers, which comprise the two sections (first and second section) instead of a single block. For example, tablet computers are mono-block computing devices. For example, the computing device may be a tablet computer. In the case of tablet computers, a keyboard can be (removably) attached to the computing device, e.g. via a magnetic hinge, or via mechanically interlocking connectors. Accordingly, the computing device may be a computing device without an integrated keyboard. In other words, the computing device may be a computing device without a non-removable keyboard. However, the computing device may comprise a detachable (further) display unit and/or a detachable keyboard. For example, the computing device may be connected (or connectable) to the detachable keyboard via a hinge that is part of the keyboard or via separate hinge.

The computing device comprises the display unit 10, which in turn comprises a display of the computing device. In general, the display unit may comprise a housing for the display and the display itself. For example, the display unit may comprise additional circuitry (e.g. the one or more processors, one or more of the interfaces, one or more of the storage devices) and/or one or more additional components (such as a webcam or a biometric authentication system). For example, the display may be a user-facing display of the computing device. In general, in tablet computers and other portable computing devices, a touch-screen display may be used. In other words, the display of the computing device may be a touch-screen display. For example, the display may be a landscape-oriented display. For example, the display may have a diagonal size of at least 10 inches (or at least 12 inches, or at least 13 inches). For example, the display may be a Liquid Crystal Display, an Organic Light-Emitting Diode-based display or a Micro-Light-Emitting Diode-based display.

The computing device comprises the kickstand 20. In general, a kickstand is a stand having at least one leg that can be extended from a first position to a second position, the second position enabling the device (i.e. the computing device) to securely stand on a surface. The kickstand used in the present disclosure may comprise two legs, with one of the legs being moved between the first and second position. For example, the kickstand may comprise two legs. The kickstand may comprise a first leg 21 and a second leg 22. For example, the legs may be moveable relative to each other. In other words, an angle between the legs (i.e. an angle between the first leg and the second leg) may be adjustable relative to each other. For example, one of the legs, e.g. the second leg, may be “kicked” out (i.e. extended) relative to the other leg. For example, the angle between a first leg of the kickstand and a second leg of the kickstand may be user-adjustable. The adjustment of the angle may be either continuous (e.g. without having pre-defined angles at which the angle can be arrested) or set to a plurality pre-defined angles at which the angle can be arrested. For example, the angle between the first leg of the kickstand and the second leg of the kickstand may be continuously adjustable. For example, the angle between the first leg of the kickstand and the second leg of the kickstand may be adjustable between a plurality of pre-defined angles. For example, the plurality of angles may comprise at least a fully opened angle (i.e. a maximal angle), a closed angle, and an angle between the fully opened and the closed angle.

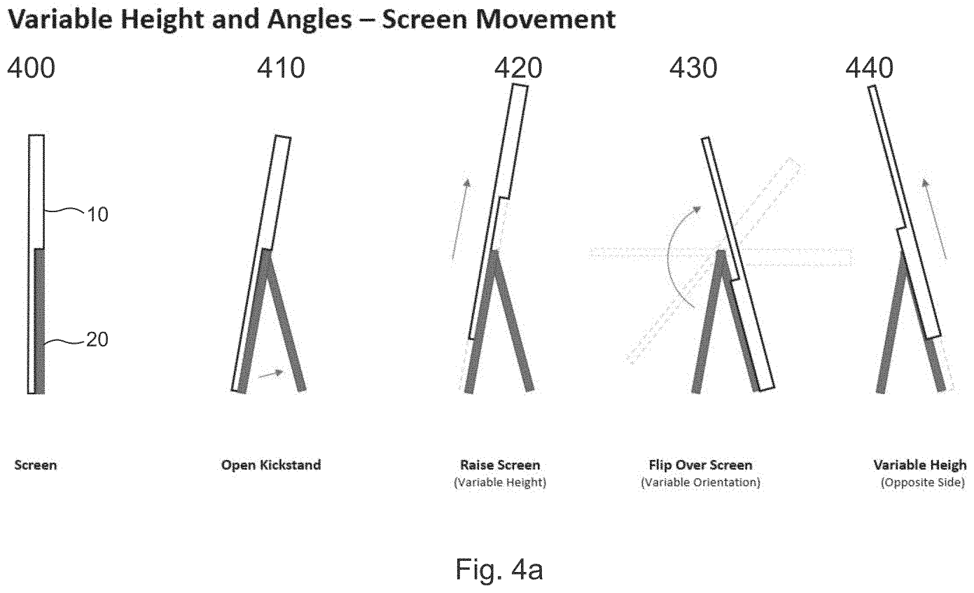

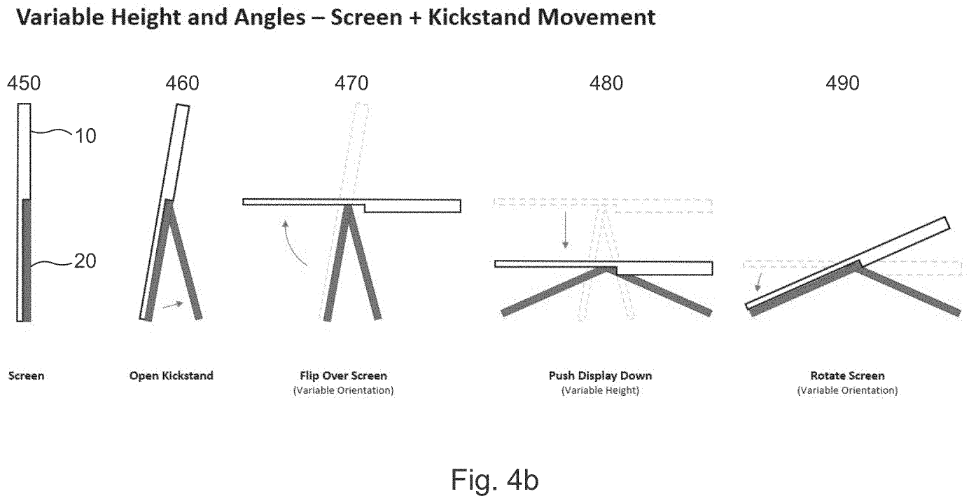

In general, the kickstand may provide a large amount of flexibility regarding the angles. For example, a maximal angle between the first leg of the kickstand and the second leg of the kickstand (i.e. an angle at which the second leg is maximally extended from the first leg) may be at least 50 degrees (or at least 60 degrees, at least 90 degrees) and/or at most 175 degrees (or at most 135 degrees). In some configurations, the computing device may be used as a drawing tablet or other stylus-based input device. In this case, a large maximal angle between the legs may be used, For example, the maximal angle between the first leg of the kickstand and the second leg of the kickstand may be at least 120 degrees (or at least 135 degrees) and/or at most 175 degrees (or at most 165 degrees). Consequently, an angle between a display surface of the display unit and a surface the computing device is placed on (e.g. a desk or table) might be at most 25 degrees (or at most 15 degrees, or at most 10 degrees) if the angle between the first leg of the kickstand and the second leg of the kickstand is set to a maximal setting. In this configuration, the computing device may be used as a drawing board or drawing tablet. For example, the display unit may comprise a touch-screen that can be used via a stylus. The angle of the display surface may be set such that a user of the computing device can use the display of the computing device as drawing tablet or stylus-based input device. Such an example is shown in FIG. 4b for example.

In various examples, the kickstand may be designed such, that, in a closed configuration, it sits flush with the other components of the computing device. In other words, the kickstand may be flush with the display unit in a closed configuration of the computing device. For example, the kickstand and the display unit may form a (substantially) even surface at the back of the computing device in the closed configuration of the computing device. Furthermore, the legs of the kickstand may be design such, that the second leg fits into a recess of the first leg. In some examples, the first leg may encompass the second leg in a closed configuration of the kickstand/computing device. For example, a first leg of the kickstand may be at least 20% wider than a second leg of the kickstand. In other words, a lateral width (i.e. a width that is in parallel to a surface on which the computing device is placed) of the first leg of the kickstand may be at least 20% larger than a lateral width of the second leg of the kickstand. For example, the second leg may fit into a recess of the first leg in a closed configuration of the kickstand/computing device. Additionally, the first leg may also be taller than the second leg, with the display unit being affixed to the first leg. For example, the first leg of the kickstand may extend at last 20% further than the second leg of the kickstand. For example, display unit may be mechanically coupled to the first leg of the kickstand.

The kickstand is mechanically coupled to the display unit via the sliding mechanism 30, such that the display unit is adjustable relative to the kickstand along the sliding mechanism. For example, the display unit is adjustable relative to the kickstand along the sliding mechanism to adjust a height of the display unit above a surface. In other words, sliding the display unit along the sliding mechanism may adjust the distance between the computing device and the surface (i.e. the height of the display unit above the surface). For example, the height may be adjustable by at least 30% (or at least 40%, or at least 50%) of a (lateral) width of the display unit. In various examples, the sliding mechanism comprises one or more pre-defined positions (or a plurality of pre-defined positions) for holding the display unit in place. These pre-defined positions may be implemented using latches, using magnets or using different amounts of friction. In other words, one or both of the legs may comprise one or more latches, one or more magnets, or one or more portions having an increased amount of friction to implement the one or more pre-defined positions.

In various examples, the sliding mechanism may be formed by the display unit and by the kickstand. In other words, the display unit and the sliding mechanism may form the sliding mechanism. For example, parts of the display unit and of the kickstand may interlock mechanically to form the sliding mechanism. In particular, the display unit may comprise one or more mechanical recesses and the kickstand comprises one or more rails that interlock with the one or more mechanical recesses to form the sliding mechanism. Alternatively, the kickstand may comprise one or more mechanical recesses that interlock with one or more rails of the display unit. In both configurations, the one or more recesses may be configured to take in the one or more rails of the kickstand in a closed configuration of the computing device. Alternatively, the sliding mechanism may be separate from the display unit and from the kickstand, e.g. a separate component.

In some examples, in addition to the sliding mechanism (or even instead of the sliding mechanism), the computing device may comprise a rotation mechanism (or rotation means) 50. For example, the display unit may be rotatable around the kickstand via a rotation mechanism. For example, the kickstand (e.g. the first leg of the kickstand) may comprise a hinge, which may implement the rotation mechanism. For example, the display unit may be rotatable around the kickstand via the rotation mechanism (only) in a fully-extended position of the sliding mechanism. For example, the rotation mechanism may be unlocked once the sliding mechanism is brought into its fully extended position. In general, the rotation mechanism may be used to adjust an angle between the display unit and a user of the computing device, or to flip the display unit onto its head, such that the display is visible from the other side of the kickstand. Such an example is shown in FIG. 4a, for example. In various examples, the rotation mechanism may be configured such, that the display unit snaps into a pre-defined position after rotating the display unit. For example, the display unit may be held at the pre-defined position by a latch, by a magnet or by gravity (and a corresponding center of mass of the display unit).

In various examples, the kickstand is used to prop up and/or rotate the display unit. To avoid instabilities, the mass of the computation device may be suitably distributed between the kickstand and the display unit. In particular, the kickstand may comprise various heavy components of the computation device. For example, the kickstand may comprise one or more processors of the computing device (and the corresponding active or passive cooling system). Additionally or alternatively, the kickstand may comprise a battery of the computing device.

Furthermore, when the display device is propped up on the kickstand, large portions of the kickstand may be exposed to the user, providing additional surface that can be used to include ports (e.g. Universal Serial Bus ports or ports for connecting an external display) or user interfaces of the computing device. For example, the kickstand may comprise one or more ports of the computing device. For example, the kickstand may comprise a power port of the computing device. For example, the kickstand may comprise a projection device for projecting a user interface or one or more further user-interface elements (such as buttons or additional touch surfaces). For example, the one or more ports, the power port, the projection device and-or the one or more further user-interface elements may be exposed in a fully-extended configuration of the kickstand.

For example, the one or more processors may be implemented using one or more processing units, one or more processing devices, any means for processing, such as a processor, a computer or a programmable hardware component being operable with accordingly adapted software. In other words, the described function of the one or more processors may as well be implemented in software, which is then executed on one or more programmable hardware components. Such hardware components may comprise a general purpose processor, a Digital Signal Processor (DSP), a micro-controller, etc. The one or more interfaces may correspond to one or more inputs and/or outputs for receiving and/or transmitting information, which may be in digital (bit) values according to a specified code, within a module, between modules or between modules of different entities. For example, the one or more interfaces may comprise interface circuitry configured to receive and/or transmit information. Ifor example, the one or more storage devices may comprise at least one element of the group of a computer readable storage medium, such as an magnetic or optical storage medium, e.g. a hard disk drive, a flash memory, Floppy-Disk, Random Access Memory (RAM), Programmable Read Only Memory (PROM), Erasable Programmable Read Only Memory (EPROM), and an Electronically Erasable Programmable Read Only Memory (EEPROM).

More details and aspects of the computation device are mentioned in connection with the proposed concept or one or more examples described above or below (e.g. FIGS. 1, 3a to 8). The computation device may comprise one or more additional optional features corresponding to one or more aspects of the proposed concept or one or more examples described above or below.

FIG. 2c shows a flow chart of an example of a method for a computation device, e.g. of a method for adjusting a computing device, e.g. the computation device shown in connection with FIGS. 2a to 2b, 3a to 8. The computing device comprises a display unit 10 and a kickstand 20. The display unit comprises a display of the computing device. In some examples, the method comprises adjusting 210 the display unit relative to the kickstand via a sliding mechanism 30 of the computing device. Alternatively or additionally, the method comprises adjusting 220 the display unit relative to the kickstand via a rotation mechanism 50 of the computing device. The method may comprise using 230 the computing device after adjusting the display unit relative to the kickstand.

More details and aspects of the computation device and of the method are mentioned in connection with the proposed concept or one or more examples described above or below (e.g. FIGS. 1 to 2b, 3a to 8). The computation device or method may comprise one or more additional optional features corresponding to one or more aspects of the proposed concept or one or more examples described above or below.

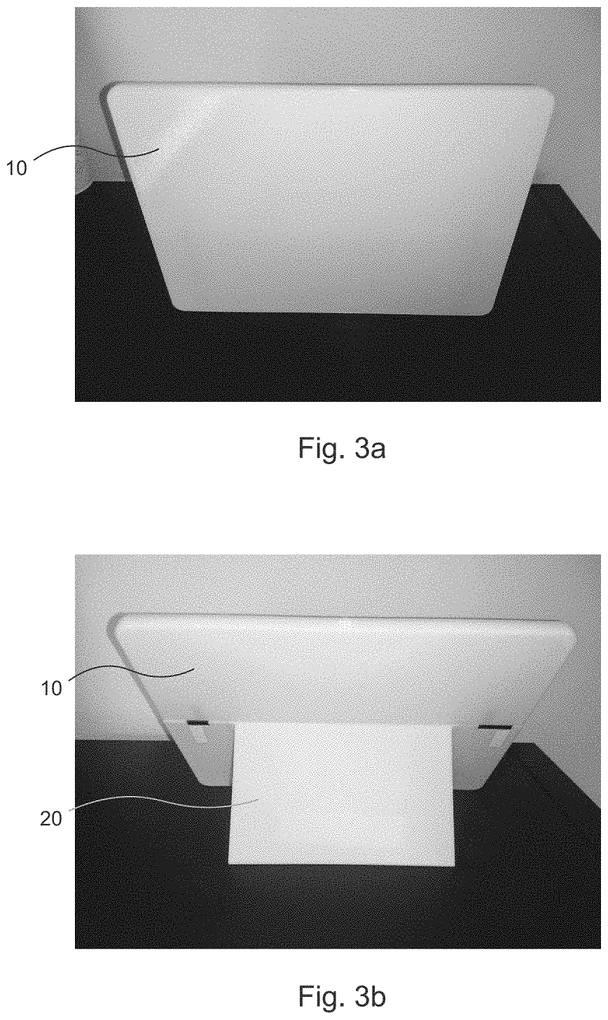

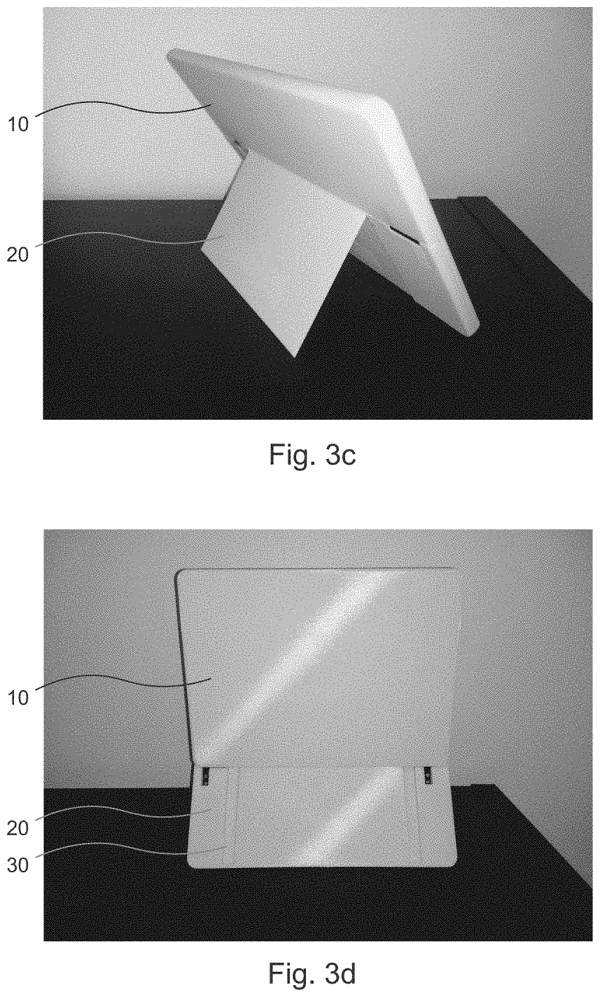

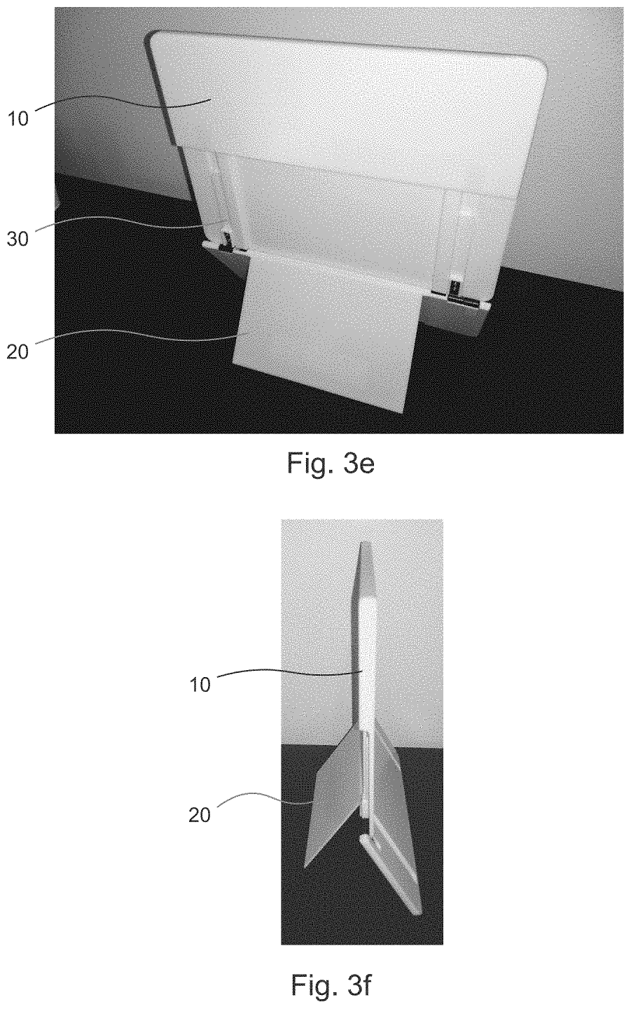

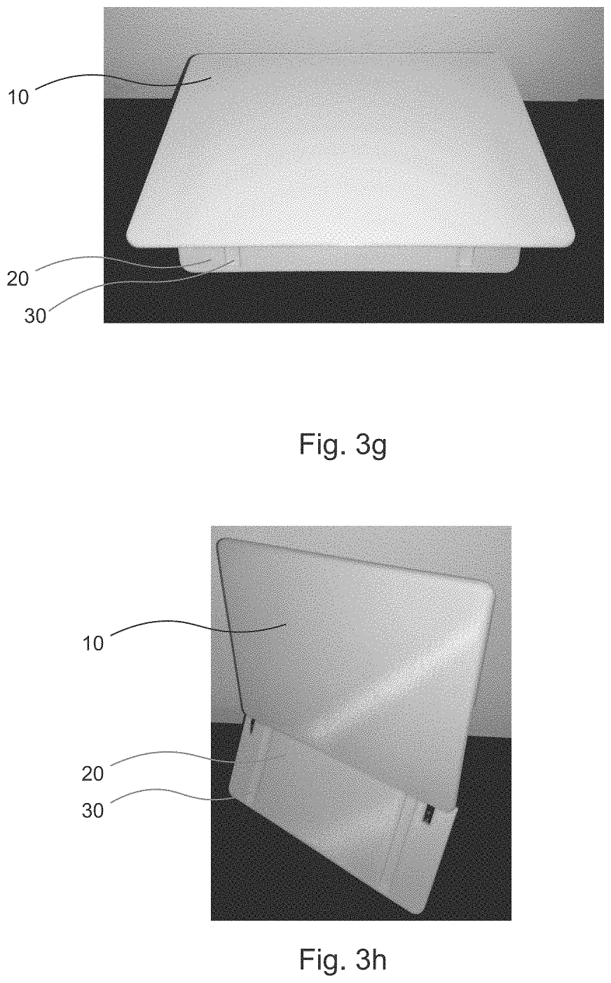

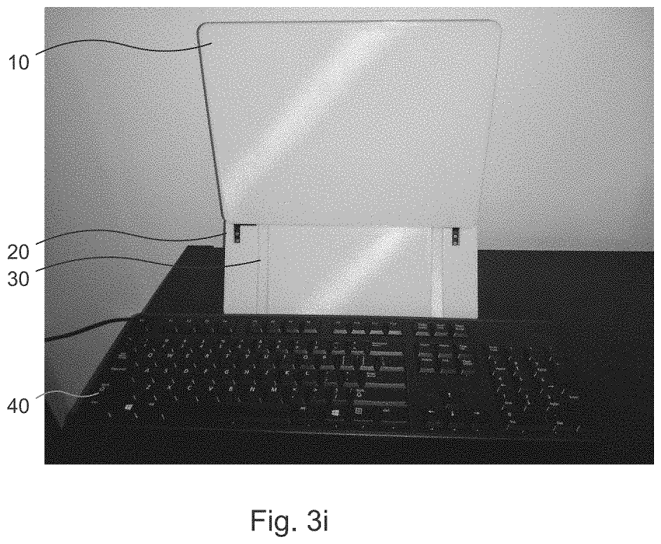

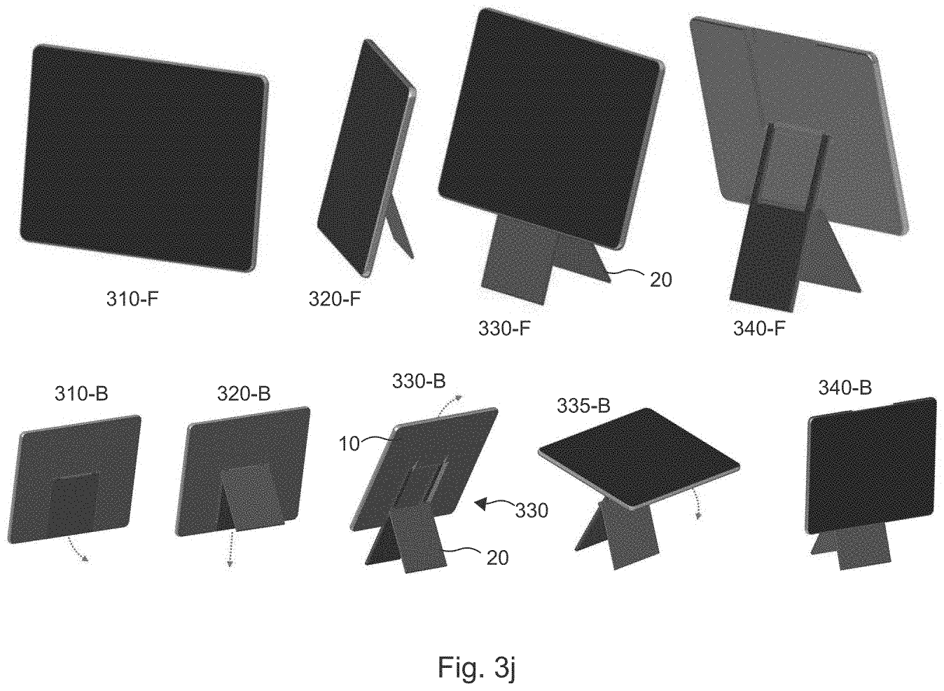

In the following, various examples are discussed in relation to FIGS. 3a to 8. As has already been shown in connection with FIGS. 1a and 2a/2b, the computing device may be or may comprise a mono-block computing device, i.e. a computing device that is monolithic, and which comprises both the display unit with the display of the computing device and the kickstand. In various examples, the display unit further comprises one or more processors, such as a central processing unit and/or a graphics processing unit of the computing device. Alternatively (or additionally), the kickstand may comprise one or more processors, such as a central processing unit and/or a graphics processing unit of the computing device. In various examples, however, the mono-block computing device might not comprise a keyboard, or the keyboard may be detachable from the mono-block computing device. In other words, the computing device may be a computing device without an integrated keyboard. For example, the computing device may be a tablet computer, i.e. a tablet computer without a permanently-attached keyboard. Accordingly, the display of the computing device may be a touch-screen display. In some examples, the computing device may be part of a two-screen computing device, or be coupled with a detachable computer. In other words, the computing device may further comprise a detachable display unit, and/or a detachable keyboard.

FIGS. 3a to 3i show an example of a computing device from different angles and in different configurations. In FIG. 3a, the screen (of the display unit 10) is shown upright with integrated kickstand (not raised). FIG. 3b shows the backside of the device, where the kickstand 20 is visible. FIG. 3c shows an angle showing an average pitch. In FIG. 3d, the display (unit) of the mono-block device is risen. FIG. 3e shows the backside of the raised screen, and FIG. 3f shows the profile of the raised screen. For example, the display unit may be adjustable relative to the kickstand along the sliding mechanism to adjust a height of the display unit above a surface, e.g. adjustable by at least 30% (or at least 40%) of a width of the display unit. In various examples, the sliding mechanism comprises one or more pre-defined positions for holding the display unit in place. These pre-defined positions may be implemented using latches, using magnets or using different amounts of friction. In FIGS. 3d and 3e, the sliding mechanism is visible. For example, parts of the display unit and of the kickstand may interlock mechanically to form the sliding mechanism. The display unit may comprise one or more mechanical recesses and the kickstand comprises one or more rails that interlock with the one or more mechanical recesses to form the sliding mechanism. The one or more recesses may be configured to take in the one or more rails of the kickstand in a closed configuration of the computing device.

The concept, as shown in FIG. 3g, may allow a flat mode (that can be raised and lowered, for optimal height in flat mode, flat onto table or higher) and gentle rotational angles to share with other users across table. In FIG. 3h, the display unit of the computation device is returned upright. In FIG. 3i, a combination with a wireless keyboard 40 is shown that is placed underneath.

More details and aspects of the computation device are mentioned in connection with the proposed concept or one or more examples described above or below (e.g. FIGS. 1 to 2c, 3j to 8). The computation device may comprise one or more additional optional features corresponding to one or more aspects of the proposed concept or one or more examples described above or below.

Turning to FIG. 3j, another example of a computing device is shown in different configurations. This example relates to a computing device with a narrow slidable kickstand for light devices, which may provide a liftable, convertible kickstand. In the following, suffixes -F and -B are used to indicate the view from the front (F) and the back (B). FIG. 3j 310-FB shows a tablet configuration, which may also be referred to as closed configuration. For example, the kickstand may be flush with the display unit in a tablet/closed configuration of the computing device. FIG. 3j 320-FB shows a kickstand tablet configuration, where the kickstand remains in the same position relative to the display unit, but a leg of the kickstand is extended. FIG. 3j 330-FB shows an elevated kickstand configuration, where the display unit is adjusted relative to the kickstand via the sliding mechanism. The display unit may be rotated 335-B to reach a configuration 340-FB in which the display unit is rotated and adjusted for comfort. For example, the display unit may be rotatable around the kickstand via a rotation mechanism. For example, the display unit may be rotatable around the kickstand via the rotation mechanism in a fully-extended position of the sliding mechanism. In various examples, the rotation mechanism is configured such, that the display unit snaps into a pre-defined position after rotating the display unit.

More details and aspects of the computation device are mentioned in connection with the proposed concept or one or more examples described above or below (e.g. FIGS. 1 to 3i, 4a to 8). The computation device may comprise one or more additional optional features corresponding to one or more aspects of the proposed concept or one or more examples described above or below.

FIGS. 4a and 4b show schematic diagrams of different positions of a display unit of a computing device relative to a kickstand of the computing device. In FIG. 4a, a change in position is shown from tablet to kickstand to raised screen and flappable display. FIG. 4a may illustrate variable height and angles with screen movement. FIG. 4a 400 shows a screen configuration, where the kickstand is flush with the display unit. In 410, the kickstand is opened. In 420, the screen is raised (with variable height). In 430, the screen is flipped over (with variable orientation), and in 440 the screen is put at a variable Hight (at the opposite side). In FIG. 4b, a change in position is shown, in which a tablet is enabled to lie flat and at an angle (e.g. for a sketching mode). FIG. 4b may illustrate variable height and angles with screen and kickstand movement. FIG. 4a 450 shows the screen configuration, in 460, the kickstand is opened. In 470, the screen is flipped over (with variable orientation), in 480, the display is pushed down (with variable height), and in 490, the screen is rotated (with variable orientation).

As is shown in more detail in FIGS. 4a and 4b, the kickstand may be adjusted as well as the position of the display unit. For example, the kickstand comprises two legs. An angle between a first leg of the kickstand and a second leg of the kickstand may be user-adjustable. For example, the angle between the first leg of the kickstand and the second leg of the kickstand may be continuously adjustable. A maximal angle between the first leg of the kickstand and the second leg of the kickstand may be at least 50 degrees (or at least 60 degrees, at least 90 degrees) and/or at most 175 degrees (or at most 135 degrees). For example, the maximal angle between the first leg of the kickstand and the second leg of the kickstand may be at least 120 degrees (or at least 135 degrees) and/or at most 175 degrees (or at most 165 degrees). Consequently, an angle between a display surface of the display unit and a surface the computing device is placed on (e.g. a desk or table) might be at most 25 degrees (or at most 15 degrees, or at most 10 degrees) if the angle between the first leg of the kickstand and the second leg of the kickstand is set to a maximal setting. In this configuration, the computing device may be used as a drawing board or drawing tablet. For example, the display unit may comprise a touch-screen that can be used via a stylus. The angle of the display surface may be set such that a user of the computing device can use the computing device as drawing tablet. For example, the angle between the legs may be maintained using a friction hinge and/or springs.

More details and aspects of the computation device are mentioned in connection with the proposed concept or one or more examples described above or below (e.g. FIGS. 1 to 3j, 5a to 8). The computation device may comprise one or more additional optional features corresponding to one or more aspects of the proposed concept or one or more examples described above or below.

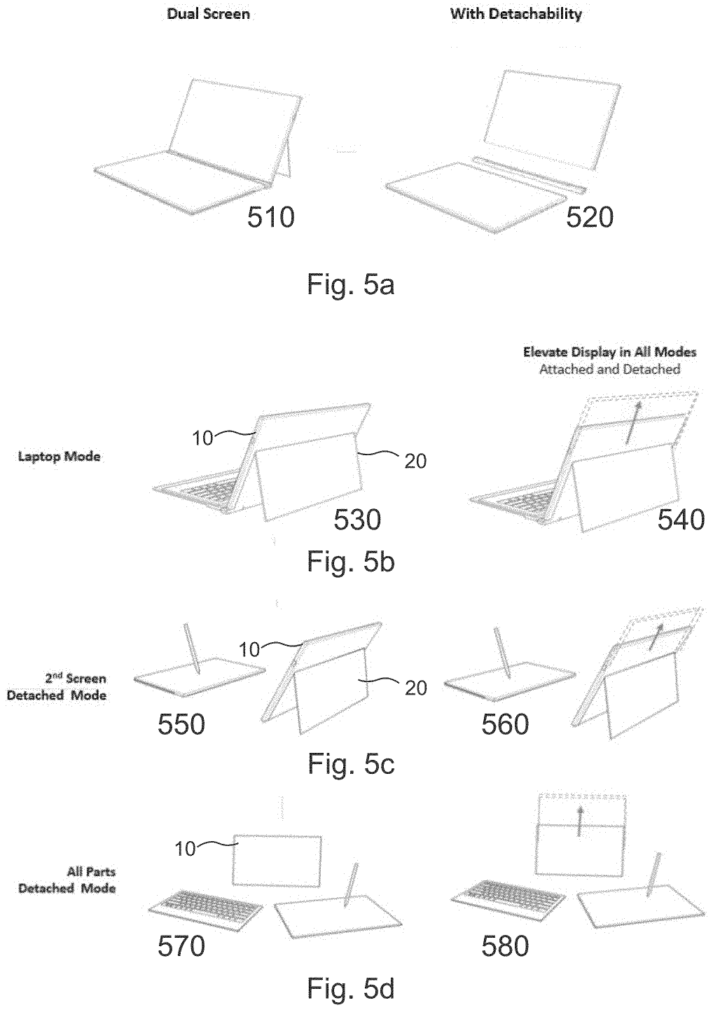

FIGS. 5a to 5d show different modes of an example of a computing device. For example, the concept can be used in variety of form factors. In FIG. 5a, a dual screen mode 510 is shown, which may be detachable (e.g. to separate the second screen from the display unit/kickstand). Examples may provide a detachable wire-free dual screen with integrated kickstand and keyboard. In 5b, the computing device is shown in laptop mode 530; 540. The display may be elevated 540, 560, 580 in all modes (attached and detached). In FIG. 5c, the computing device is shown in second screen detached mode (550, 560 with elevated display). In FIG. 5d, the computing device is shown in all parts detached mode (two screens and keyboard) 570, elevated mode 580.

More details and aspects of the computation device are mentioned in connection with the proposed concept or one or more examples described above or below (e.g. FIGS. 1 to 4b, 6 to 8). The computation device may comprise one or more additional optional features corresponding to one or more aspects of the proposed concept or one or more examples described above or below.

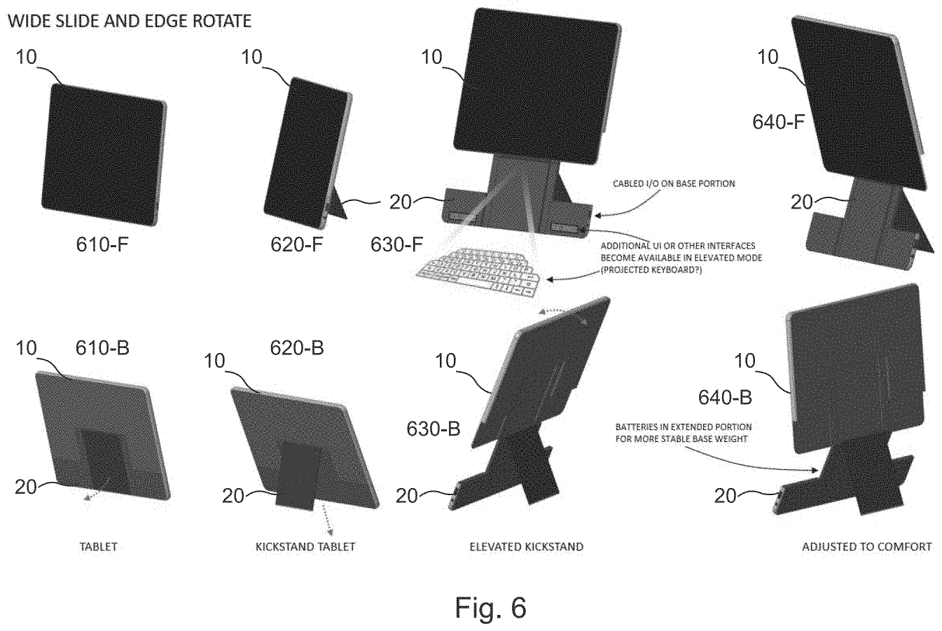

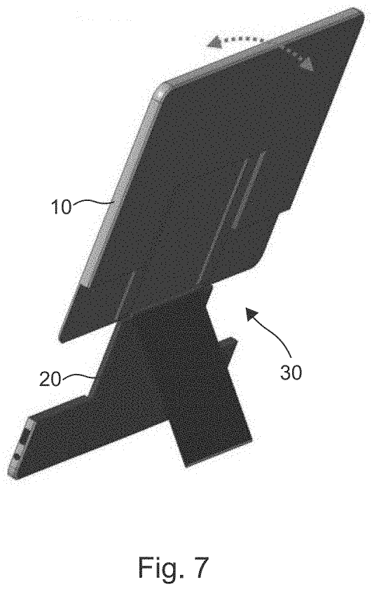

FIGS. 6 and 7 show an example of a computing device with a wide slidable kickstand for larger and heavier devices. The battery can be placed in the kickstand, so it is at table level and the gravity center is lower. FIG. 6 shows another example of a computing device in different configurations. The example in FIG. 6 is denoted wide slide (as it has a kickstand with a wide base), and edge rotate (as the display unit is rotatable at the edge of the kickstand. The following configurations are similar to the configurations shown in relation with FIGS. 3 and 4a/b. 610-FB a shows a tablet configuration, and 620-FB shows a kickstand tablet configuration. 630-FB shows an elevated kickstand configuration with a projected keyboard. For example, one of the legs may be wider than the other to take in various components of the computing device. For example, a first leg of the kickstand may be at least 20% wider than a second leg of the kickstand. For example, cabled input/output ports may be arranged on the base portion (i.e. the wider leg of the kickstand). In some examples, both legs of the kickstand may be wider and contain components of the computing device. For example, the kickstand may comprise one or more processors, one or more sensors, one or more storage devices, one or more projection devices etc., which may become available as the display unit is raised up. Additional user interface or other interfaces may become available in elevated mode (projected mode), e.g. via a projector and/or a depth sensor that are integrated in the kickstand. For example, the kickstand may comprise one or more processors of the computing device, a battery of the computing device, one or more ports of the computing device, a power port of the computing device and/or a projection device for projecting a user interface (or a combination thereof). In 640-FB, the display unit is adjusted to comfort (with the display facing downward towards the user). Batteries may be included in the extended portion of the kickstand for more stable base weight.

FIG. 7 shows an example of a computing device, in which a display unit of the computing device is tilted around a kickstand of the computing device. FIG. 7 may show a wide slidable kickstand for larger and heavier devices. The battery can be placed in the kickstand, so it is at table level and the gravity center is lower.

If a processor/graphics unit, a projection device, a sensor and/or ports are integrated in the kickstand, the computing device may further comprise a power interconnect and/or a data interconnect between the processor/graphics unit and the display unit, and/or between the projection device, sensor and/or ports and a processor integrated in the display unit (if the processor/graphics unit is not integrated of the kickstand). For that, flexible cables, sliding contacts (at least for power) and/or wireless data transmission may be used. In some examples, the display unit may comprise a sensor for sensing an orientation of the display unit, e.g. to enable adjusting the displayed content to the sensed orientation.

More details and aspects of the computation device are mentioned in connection with the proposed concept or one or more examples described above or below (e.g. FIGS. 1 to 5d, 8). The computation device may comprise one or more additional optional features corresponding to one or more aspects of the proposed concept or one or more examples described above or below.

In some examples, the computing device might only comprise a rotation mechanism, without a sliding mechanism. Examples further provide a computing device comprising a display unit 10 comprising a display of the computing device, and a kickstand 20. The kickstand is mechanically coupled to the display unit via a rotation mechanism 50, such that the display unit is adjustable relative to the kickstand via the rotation mechanism. Accordingly, examples further provide a method for adjusting a computing device, the method comprising adjusting the display unit relative to the kickstand via a rotation mechanism 50 of the computing device. For example, the rotation mechanism may be configured such, that the display unit snaps into a pre-defined position after rotating the display unit. For example, the computation device may be implemented similar to the computation devices introduced in connection with FIGS. 2a to 7.

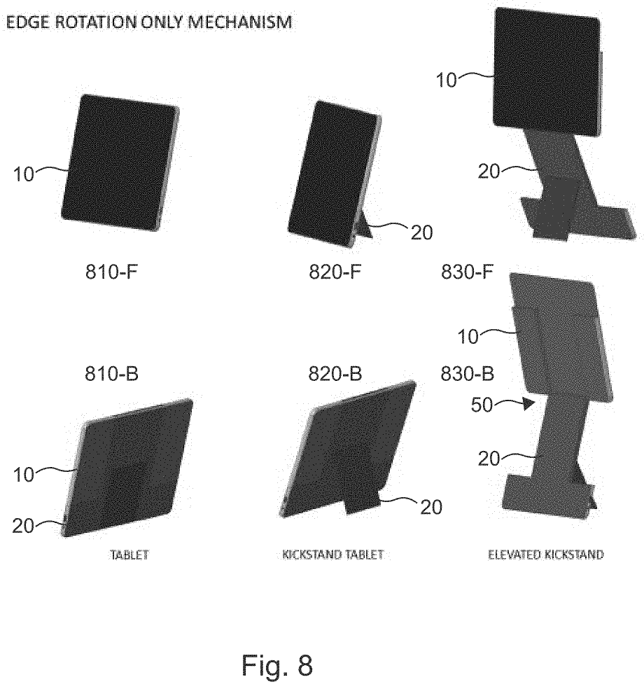

FIG. 8 shows an example of such a computing device with a rotation mechanism in different configurations. The following example is denoted an “edge rotation only mechanism”, as it foregoes the sliding mechanism. A turnable kickstand mechanism (with a rotation mechanism) may allow to lift the screen higher. In FIG. 8, one leg of the kickstands extends further than the other, e.g. to enable adjusting the height of the display unit. Accordingly, a first leg of the kickstand may extend at last 20% further than a second leg of the kickstand. FIG. 8 shows the computing device in a tablet configuration 810-FB, a kickstand tablet configuration 820-FB and an elevated kickstand configuration 830-FB, where the display unit is rotated around the edge of the kickstand to increase the height above the surface. The top of display unit may be tilted upward to balance the display unit atop the kickstand.

More details and aspects of the computation device are mentioned in connection with the proposed concept or one or more examples described above or below (e.g. FIGS. 1 to 7). The computation device may comprise one or more additional optional features corresponding to one or more aspects of the proposed concept or one or more examples described above or below.

The aspects and features mentioned and described together with one or more of the previously detailed examples and figures, may as well be combined with one or more of the other examples in order to replace a like feature of the other example or in order to additionally introduce the feature to the other example.

Example 1 relates to a computing device comprising a display unit (10) comprising a display of the computing device. The computing device comprises a kickstand (20), wherein the kickstand is mechanically coupled to the display unit via a sliding mechanism (30), such that the display unit is adjustable relative to the kickstand along the sliding mechanism.

In Example 2, the subject matter of example 1 or any of the Examples described herein may further include, that parts of the display unit and of the kickstand interlock mechanically to form the sliding mechanism.

In Example 3, the subject matter of one of the examples 1 to 2 or any of the Examples described herein may further include, that the display unit comprises one or more mechanical recesses and the kickstand comprises one or more rails that interlock with the one or more mechanical recesses to form the sliding mechanism.

In Example 4, the subject matter of example 3 or any of the Examples described herein may further include, that the one or more recesses are configured to take in the one or more rails of the kickstand in a closed configuration of the computing device.

In Example 5, the subject matter of one of the examples 1 to 4 or any of the Examples described herein may further include, that the kickstand is flush with the display unit in a closed configuration of the computing device.

In Example 6, the subject matter of one of the examples 1 to 5 or any of the Examples described herein may further include, that the display unit is adjustable relative to the kickstand along the sliding mechanism to adjust a height of the display unit above a surface.

In Example 7, the subject matter of example 6 or any of the Examples described herein may further include, that the height is adjustable by at least 30% of a width of the display unit.

In Example 8, the subject matter of one of the examples 1 to 7 or any of the Examples described herein may further include, that the display unit is rotatable around the kickstand via a rotation mechanism.

In Example 9, the subject matter of example 8 or any of the Examples described herein may further include, that the display unit is rotatable around the kickstand via the rotation mechanism in a fully-extended position of the sliding mechanism.

In Example 10, the subject matter of one of the examples 8 to 9 or any of the Examples described herein may further include, that the rotation mechanism is configured such, that the display unit snaps into a pre-defined position after rotating the display unit.

In Example 11, the subject matter of one of the examples 1 to 10 or any of the Examples described herein may further include, that the sliding mechanism comprises one or more pre-defined positions for holding the display unit in place.

In Example 12, the subject matter of one of the examples 1 to 11 or any of the Examples described herein may further include, that the kickstand comprises two legs.

In Example 13, the subject matter of example 12 or any of the Examples described herein may further include, that a first leg of the kickstand is at least 20% wider than a second leg of the kickstand.

In Example 14, the subject matter of one of the examples 12 to 13 or any of the Examples described herein may further include, that a first leg of the kickstand extends at last 20% further than a second leg of the kickstand.

In Example 15, the subject matter of one of the examples 12 to 14 or any of the Examples described herein may further include, that an angle between a first leg of the kickstand and a second leg of the kickstand is user-adjustable.

In Example 16, the subject matter of one of the examples 12 to 15 or any of the Examples described herein may further include, that the angle between the first leg of the kickstand and the second leg of the kickstand is continuously adjustable.

In Example 17, the subject matter of one of the examples 12 to 16 or any of the Examples described herein may further include, that a maximal angle between the first leg of the kickstand and the second leg of the kickstand is at least 50 degrees and/or at most 175 degrees.

In Example 18, the subject matter of one of the examples 12 to 17 or any of the Examples described herein may further include, that a maximal angle between the first leg of the kickstand and the second leg of the kickstand is at least 120 degrees and/or at most 175 degrees.

In Example 19, the subject matter of example 18 or any of the Examples described herein may further include, that an angle between a display surface of the display unit and a surface the computing device is placed on is at most 25 degrees if the angle between the first leg of the kickstand and the second leg of the kickstand is set to a maximal setting.

In Example 20, the subject matter of one of the examples 1 to 19 or any of the Examples described herein may further include, that the kickstand comprises one or more processors of the computing device.

In Example 21, the subject matter of one of the examples 1 to 20 or any of the Examples described herein may further include, that the kickstand comprises a battery of the computing device.

In Example 22, the subject matter of one of the examples 1 to 21 or any of the Examples described herein may further include, that the kickstand comprises one or more ports of the computing device.

In Example 23, the subject matter of one of the examples 1 to 22 or any of the Examples described herein may further include, that the kickstand comprises a power port of the computing device.

In Example 24, the subject matter of one of the examples 1 to 23 or any of the Examples described herein may further include, that the kickstand comprises a projection device for projecting a user interface.

In Example 25, the subject matter of one of the examples 1 to 24 or any of the Examples described herein may further include, that the computing device is a mono-block computing device.

In Example 26, the subject matter of one of the examples 1 to 25 or any of the Examples described herein may further include, that the computing device is a computing device without an integrated keyboard.

In Example 27, the subject matter of one of the examples 1 to 26 or any of the Examples described herein may further include, that the computing device is a tablet computer.

In Example 28, the subject matter of one of the examples 1 to 27 or any of the Examples described herein may further include, that the display of the computing device is a touch-screen display.

In Example 29, the subject matter of one of the examples 1 to 28 or any of the Examples described herein may further include, that the computing device further comprises a detachable display unit and/or a detachable keyboard.

Example 30 relates to a computing device comprising a display unit (10) comprising a display of the computing device. The computing device comprises a kickstand (20), wherein the kickstand is mechanically coupled to the display unit via a rotation mechanism (50), such that the display unit is adjustable relative to the kickstand via the rotation mechanism.

In Example 31, the subject matter of example 30 or any of the Examples described herein may further include, that the rotation mechanism is configured such, that the display unit snaps into a pre-defined position after rotating the display unit.

In Example 32, the subject matter of one of the examples 30 to 31 or any of the Examples described herein may further include, that the kickstand comprises one or more processors of the computing device.

In Example 33, the subject matter of one of the examples 30 to 32 or any of the Examples described herein may further include, that the kickstand comprises a battery of the computing device.

In Example 34, the subject matter of one of the examples 30 to 33 or any of the Examples described herein may further include, that the kickstand comprises one or more ports of the computing device.

In Example 35, the subject matter of one of the examples 30 to 34 or any of the Examples described herein may further include, that the kickstand comprises a power port of the computing device.

In Example 36, the subject matter of one of the examples 30 to 35 or any of the Examples described herein may further include, that the kickstand comprises a projection device for projecting a user interface.

In Example 37, the subject matter of one of the examples 30 to 36 or any of the Examples described herein may further include, that the computing device is a mono-block computing device.

In Example 38, the subject matter of one of the examples 30 to 37 or any of the Examples described herein may further include, that the computing device is a computing device without an integrated keyboard.

In Example 39, the subject matter of one of the examples 30 to 38 or any of the Examples described herein may further include, that the computing device is a tablet computer.

In Example 40, the subject matter of one of the examples 30 to 39 or any of the Examples described herein may further include, that the display of the computing device is a touch-screen display.

In Example 41, the subject matter of one of the examples 30 to 40 or any of the Examples described herein may further include, that the computing device further comprises a detachable display unit and/or a detachable keyboard.

Example 42 relates to a method for adjusting a computing device, the computing device comprising a display unit (10) and a kickstand (20), the display unit comprising a display of the computing device, the method comprising adjusting the display unit relative to the kickstand via a sliding mechanism (30) of the computing device. The method may comprise using the computing device after adjusting the display unit relative to the kickstand.

In Example 43, the subject matter of example 42 or any of the Examples described herein may further include, that the method comprises adjusting the display unit relative to the kickstand via a rotation mechanism (50) of the computing device.

Example 44 relates to a method for adjusting a computing device, the computing device comprising a display unit (10) and a kickstand (20), the display unit comprising a display of the computing device, the method comprising adjusting the display unit relative to the kickstand via a rotation mechanism (50) of the computing device. The method may comprise using the computing device after adjusting the display unit relative to the kickstand.

In Example 45, the subject matter of example 44 or any of the Examples described herein may further include, that the method comprises comprising adjusting the display unit relative to the kickstand via a sliding mechanism (30) of the computing device.

Example 46 relates to a computing apparatus comprising a display unit (10) comprising a display means of the computing device. The computing apparatus comprises a kickstand (20), wherein the kickstand is mechanically coupled to the display unit via a sliding means (30), such that the display unit is adjustable relative to the kickstand along the sliding means.

In Example 47, the subject matter of example 46 or any of the Examples described herein may further include, that the display unit is rotatable around the kickstand via a rotation means.

Example 48 relates to a computing apparatus comprising a display unit (10) comprising a display means of the computing device. The computing apparatus comprises a kickstand (20), wherein the kickstand is mechanically coupled to the display unit via a rotation means (50), such that the display unit is adjustable relative to the kickstand via the rotation means.

In Example 49, the subject matter of example 48 or any of the Examples described herein may further include, that the kickstand is mechanically coupled to the display unit via the rotation means and via a sliding means (30), such that the display unit is adjustable relative to the kickstand along the sliding means.

Examples may further be or relate to a computer program having a program code for performing one or more of the above methods, when the computer program is executed on a computer or processor. Steps, operations or processes of various above-described methods may be performed by programmed computers or processors. Examples may also cover program storage devices such as digital data storage media, which are machine, processor or computer readable and encode machine-executable, processor-executable or computer-executable programs of instructions. The instructions perform or cause performing some or all of the acts of the above-described methods. The program storage devices may comprise or be, for instance, digital memories, magnetic storage media such as magnetic disks and magnetic tapes, hard drives, or optically readable digital data storage media. Further examples may also cover computers, processors or control units programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

A functional block denoted as “means for . . . ” performing a certain function may refer to a circuit that is configured to perform a certain function. Hence, a “means for s.th.” may be implemented as a “means configured to or suited for s.th.”, such as a device or a circuit configured to or suited for the respective task.

Functions of various elements shown in the figures, including any functional blocks labeled as “means”, “means for providing a signal”, “means for generating a signal.”, etc., may be implemented in the form of dedicated hardware, such as “a signal provider”, “a signal processing unit”, “a processor”, “a controller”, etc. as well as hardware capable of executing software in association with appropriate software. When provided by a processor, the functions may be provided by a single dedicated processor, by a single shared processor, or by a plurality of individual processors, some of which or all of which may be shared. However, the term “processor” or “controller” is by far not limited to hardware exclusively capable of executing software, but may include digital signal processor (DSP) hardware, network processor, application specific integrated circuit (ASIC), field programmable gate array (FPGA), read only memory (ROM) for storing software, random access memory (RAM), and nonvolatile storage. Other hardware, conventional and/or custom, may also be included.

A block diagram may, for instance, illustrate a high-level circuit diagram implementing the principles of the disclosure. Similarly, a flow chart, a flow diagram, a state transition diagram, a pseudo code, and the like may represent various processes, operations or steps, which may, for instance, be substantially represented in computer readable medium and so executed by a computer or processor, whether or not such computer or processor is explicitly shown. Methods disclosed in the specification or in the claims may be implemented by a device having means for performing each of the respective acts of these methods.

It is to be understood that the disclosure of multiple acts, processes, operations, steps or functions disclosed in the specification or claims may not be construed as to be within the specific order, unless explicitly or implicitly stated otherwise, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or—steps, respectively. Such sub acts may be included and part of the disclosure of this single act unless explicitly excluded.

Furthermore, the following claims are hereby incorporated into the detailed description, where each claim may stand on its own as a separate example. While each claim may stand on its own as a separate example, it is to be noted that—although a dependent claim may refer in the claims to a specific combination with one or more other claims—other examples may also include a combination of the dependent claim with the subject matter of each other dependent or independent claim. Such combinations are explicitly proposed herein unless it is stated that a specific combination is not intended. Furthermore, it is intended to include also features of a claim to any other independent claim even if this claim is not directly made dependent to the independent claim.

What is claimed is:

1. A computing device comprising:
a display unit comprising a display of the computing device; and
a kickstand,
wherein the kickstand is mechanically coupled to the display unit via a sliding mechanism, such that the display unit is adjustable relative to the kickstand along the sliding mechanism.

2. The computing device according to claim 1, wherein parts of the display unit and of the kickstand interlock mechanically to form the sliding mechanism.

3. The computing device according to claim 1, wherein the display unit comprises one or more mechanical recesses and the kickstand comprises one or more rails that interlock with the one or more mechanical recesses to form the sliding mechanism.

4. The computing device according to claim 3, wherein the one or more recesses are configured to take in the one or more rails of the kickstand in a closed configuration of the computing device.

5. The computing device according to claim 1 wherein the kickstand is flush with the display unit in a closed configuration of the computing device.

6. The computing device according to claim 1, wherein the display unit is adjustable relative to the kickstand along the sliding mechanism to adjust a height of the display unit above a surface.

7. The computing device according to claim 1, wherein the display unit is rotatable around the kickstand via a rotation mechanism.

8. The computing device according to claim 7, wherein the display unit is rotatable around the kickstand via the rotation mechanism in a fully-extended position of the sliding mechanism.

9. The computing device according to claim 7, wherein the rotation mechanism is configured such, that the display unit snaps into a pre-defined position after rotating the display unit.

10. The computing device according to claim 1, wherein the sliding mechanism comprises one or more pre-defined positions for holding the display unit in place.

11. The computing device according to claim 1, wherein the kickstand comprises two legs.

12. The computing device according to claim 11, wherein an angle between a first leg of the kickstand and a second leg of the kickstand is user-adjustable.

13. The computing device according to claim 11, wherein a maximal angle between the first leg of the kickstand and the second leg of the kickstand is at least 50 degrees and/or at most 175 degrees.

14. The computing device according to claim 11, wherein a maximal angle between the first leg of the kickstand and the second leg of the kickstand is at least 120 degrees and/or at most 175 degrees, wherein an angle between a display surface of the display unit and a surface the computing device is placed on is at most 25 degrees if the angle between the first leg of the kickstand and the second leg of the kickstand is set to a maximal setting.

15. A computing device comprising:
a display unit comprising a display of the computing device; and
a kickstand,
wherein the kickstand is mechanically coupled to the display unit via a rotation mechanism, such that the display unit is adjustable relative to the kickstand via the rotation mechanism.

16. The computing device according to claim 15, wherein the rotation mechanism is configured such, that the display unit snaps into a pre-defined position after rotating the display unit.

17. A method for a computing device, the computing device comprising a display unit and a kickstand, the display unit comprising a display of the computing device, the method comprising:
adjusting the display unit relative to the kickstand via a sliding mechanism of the computing device; and
using the computing device after adjusting the display unit relative to the kickstand.

18. The method according to claim 17, wherein the method comprises adjusting the display unit relative to the kickstand via a rotation mechanism of the computing device.

19. A method for adjusting a computing device, the computing device comprising a display unit and a kickstand, the display unit comprising a display of the computing device, the method comprising:
adjusting the display unit relative to the kickstand via a rotation mechanism of the computing device; and
using the computing device after adjusting the display unit relative to the kickstand.

20. The method according to claim 19, wherein the method comprises comprising adjusting the display unit relative to the kickstand via a sliding mechanism of the computing device.
